(19) United States
(12) Patent Application Publication
(10) Pub. No.: US 2007/0145543 A1
(43) Pub. Date: Jun. 28, 2007

(54) Plating bar design for high speed package design

(76) Inventors: Xiang Yin Zeng, Shanghai (CN); Jiangqi He, Gilbert, AZ (US); Dong-Ho Han, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/320,274

(22) Filed: Dec. 28, 2005

(51) Int. Cl. H01L 29/40

(52) U.S. Cl. 257/664; 257/692; 257/E23.151; 257/E23.174

(57) ABSTRACT

A method including modifying a characteristic impedance along a length of a plating bar of a substrate package. An apparatus including a package substrate including a plurality of transmission lines therethrough, a portion of the plurality of transmission lines each including a plating bar coupled thereto, wherein the plating bar comprises portions having different characteristic impedance along its length. A system including a computing device including a microprocessor, the microprocessor coupled to a printed circuit board through a substrate, the substrate including a plurality of transmission lines therethrough, a portion of the plurality of transmission lines each including a plating bar coupled thereto, wherein the plating bar comprises portions having different characteristic impedance along its length.

### FIELD OF THE INVENTION

Integrated circuit packaging.

### BACKGROUND

Integrated circuits are typically enclosed by a package that is mounted to printed circuit board. One representative example includes a package that has a number of exposed contacts that are wirebonded to surface tags of the integrated circuits or connected to the printed circuit board through solder balls and dedicated to the various power, ground and signal lines of the integrated circuit. The exposed contacts in package substrate for bonding wires are typically called bond fingers. In one embodiment, a package substrate of a package has internal routing layers that connect solder ball contacts on the substrate to the bond fingers. The internal routing typically contains several layers for a ground bus, a power bus, a number of signal lines. The various layers are connected by vias. The conductor layers in virtually all packages are made of copper. However, the poor corrosion properties of the copper make it unsuitable for practical application because in the presence of moisture, bare copper is easily tarnished making it unsuitable for subsequent assembly operations. A remedy choice is to cover the copper conductor layers using some metal materials having excellent corrosion resistance, like nickel and gold. Electroplating isone approach to cover the copper conductive layers with a corrosion resistant material is by electroplating.

During the manufacturing process of a package substrate using an electroplating method, the contact points are typically routed by plating bars to edge metallization that is used to provide an electrical current (e.g., a direct current) to allow plating of the contact points (e.g., plating with copper and/or gold). Following plating, the edge metallization is removed in a singulation process in assembly so that the plating bars are disconnected from each other. The remaining plating bars can create undesirable capacitance and signal reflection in the package. When a length of a plating bar is close to one quarter of the operating wavelength, a full reflection can happen.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a computer system including a package including a microprocessor coupled to a printed circuit board.

FIG. 2 is a top planar view of a package substrate.

FIG. 3 is a schematic side view of an embodiment of a plating bar connected to a transmission line of a package substrate.

FIG. 4 is a top view of a package substrate that shows another embodiment of a plating bar connected to a transmission line.

FIG. 5 is a schematic planar top view of a plating bar on a package substrate according to another embodiment.

### DETAILED DESCRIPTION

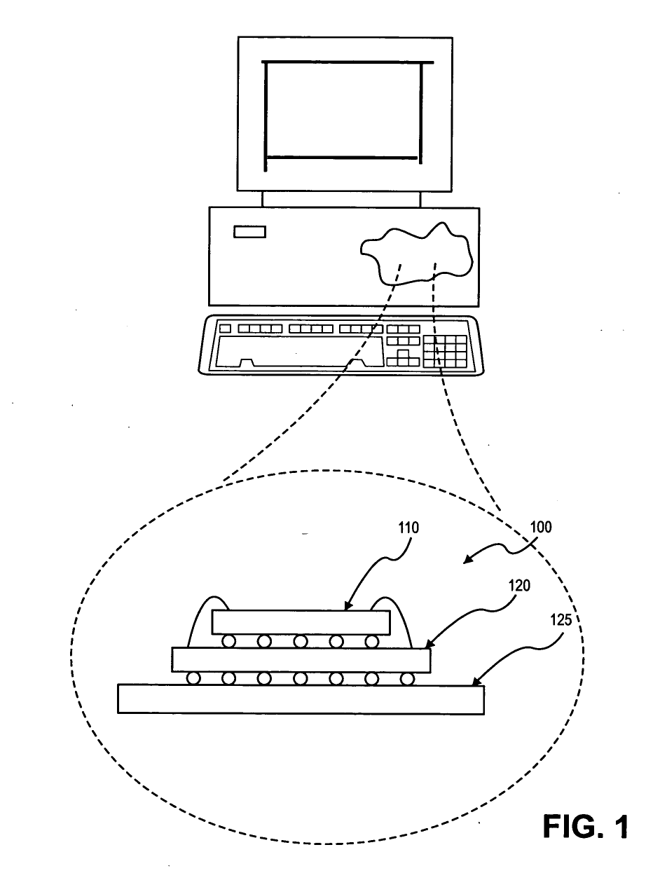

FIG. 1 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, handheld, server, etc.), wireless communication device (e.g., cellular phone, cordless phone, pager, etc.), computer-related peripheral (e.g., printer, scanner, monitor, etc.), entertainment device (e.g., television, radio, stereo, tapes and compact disc player, video cassette recorder, motion picture experts group, Audio Layer 3 player (MP3), etc.), and the like. FIG. 1 illustrates the electronic assembly as part of a desktop computer. FIG. 1 shows electronic assembly 100 including die 110, physically and electrically connected to package substrate 120. Die 110 is an integrated circuit die, such as a microprocessor die, having, for example, transistor structures interconnected or connected to power/ground or input/output signals external to the die. Electrical contact points (e.g., contact pads on a surface of die 110) are connected to substrate package 120 through, for example, a conductive bump layer and/or wire bonds. Package substrate 120 may be used to connect die 110 to printed circuit board 125, such as a motherboard or other circuit board.

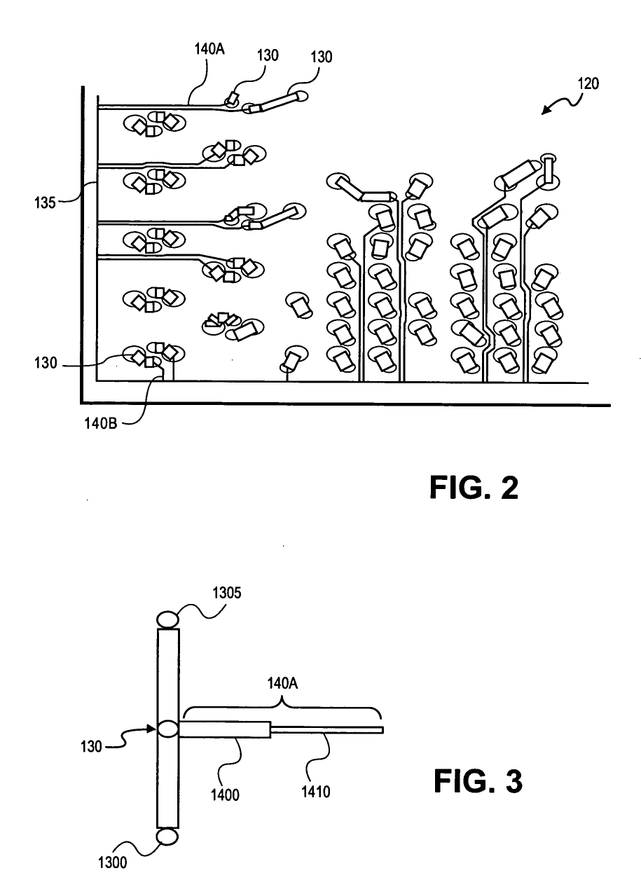

FIG. 2 shows a schematic planar top view of package substrate 120. Package substrate 120 includes a number of contact points 130 that are used, for example, as wire bond contact points. Representatively, contact points 130 are of a copper material coated with a corrosion/oxidation resistant material An electroplating process to coat contact points 130 with a corrosion resistant material requires contact points 130 be connected to an electrical source. One technique for connecting contact points 130 to an electrical source requires circuit lines to connect the contact points-together from layer to layer for connection to sacrificial edge metallization. The edge metallization allows package substrate 120 to be clipped onto a plating rack fixture for electrical contact. The plating rack may be hung on a cathode bar for plating. Following plating, the edge metallization is typically separated from the plating bars in a singulation process that separates a number of package produced simultaneously into individual packages. The plating bars typically remain in/on the package.

FIG. 2 shows edge metallization 135 of, for example, a copper material extending along a perimeter of package substrate 120. Contact points 130 are electrically connected to edge metallization 135 through plating bars 140A and 140B. The plating bars and edge metallization may be formed by physical or chemical deposition processes.

Contact points 130 in/on package substrate 120 of FIG. 2 may be used, for example, in high speed input/output (I/O) operations like I/O controller hub configurations. As the I/O signal speed increases and the operating frequency increases, plating bars become electrically long in the sense that the plating bar resonance can add a short circuit to a transmission line (e.g., when the plating bar length is close to one quarter of the wavelength), making the signal reflect back to a transmitter. In other words, at increased signal frequency, signal wavelength is typically shortened. The effect of this on a plating bar having a constant physical length is that the electrical length of the plating bar is increased with increased frequency. The increased electrical length and associated resonance can lead to short circuits. FIG. 2 shows an example of physically long plating bar 140A compared to physically short plating bar 140B. Representatively, plating bar 140A having a physical length of several millimeters presents concerns over resonance at frequencies of several gigahertz (GHz) compared to plating bar 140B having a representative physical length less than one millimeter.

One technique for shifting plating bar resonant frequency to higher is to modify a characteristic impedance along the length of the plating bar. Such modification may be limited to those plating bars deemed electrically long in any particular application. FIG. 3 shows an embodiment where plating bar 140A is designated in two sections 1400 and 1410. Section 1400 is closer to contact point or transmission line 130. FIG. 3 shows transmission line 130 extending between input port 1300 and output port 1305. Referring again to plating bar 140A, FIG. 3 shows section 1400 having a thickness or width dimension that is greater than a thickness or width dimension of section 1410. Thus, assuming section 1400 and section 1410 have similar lengths, section 1400 should have a smaller characteristic impedance than section 1410. It is appreciated that a plating bar may be designated into a number of section, including more than two sections. Also, in this embodiment, the characteristic impedance is shown to increase from the transmission line towards a point, for example, towards edge metallization.

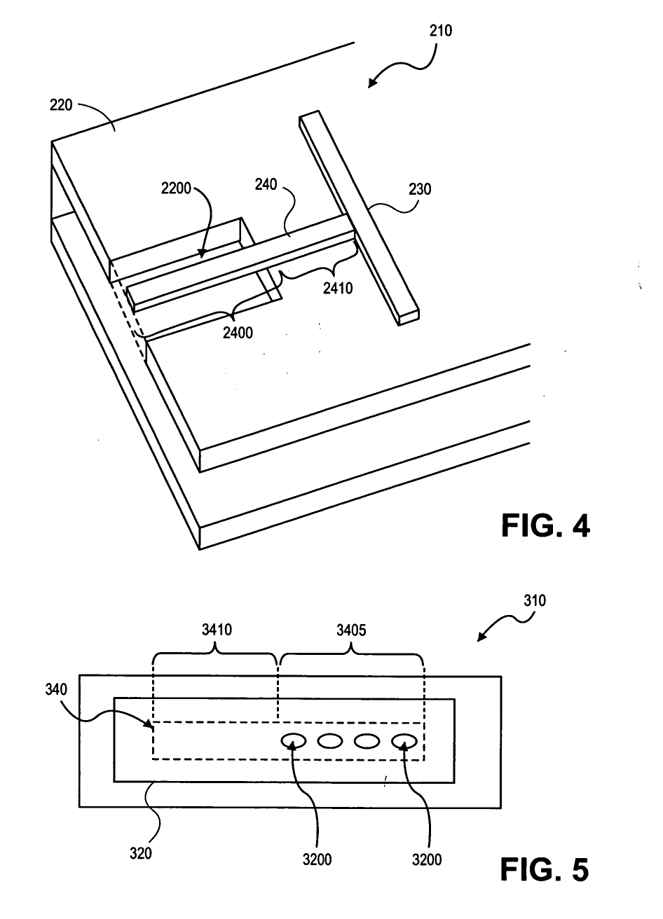

FIG. 4 shows a top perspective view of another embodiment of a package substrate. In this embodiment, package substrate 210 includes ground plane 220 disposed in a plane of the package. FIG. 4 also shows transmission line or signal trace 230 disposed above ground plane 220, as viewed. Plating bar 240 is connected to signal trace 230 and is routed to edge metallization (not shown). Plating bar 240, in this embodiment, is designated into sections 2400 and 2410, with section 2410 being proximate to signal trace 230. To modify a characteristic impedance of plating bar 240, in this embodiment, opening 2200 is created in ground plane 220 beneath section 2400 of plating bar 240. Placing the opening beneath section 2400 of plating bar 240 tends to increase the characteristic impedance of the plating bar in this section relative to section 2410.

FIG. 5 shows a schematic top view of a portion of a package substrate. In this embodiment, package substrate 310 includes ground portion or ground plane 320 disposed in the substrate. Overlying ground plane 320 is plating bar 340 shown in dashed lines. Plating bar 340 includes section 3405 and section 3410. Section 3410, in one embodiment, is positioned closer to a signal trace or transmission line than section 3405. In this embodiment, ground plane 320 includes a number of openings 3200 in the ground plane corresponding to and aligned with section 3405 of plating bar 3340. Openings 3200 in ground plane 320 tend to increase the characteristic impedance of the plating bar in section 3405 relative to section 3410.

In the above embodiments, various techniques for modifying a characteristic impedance of a plating bar along its length are disclosed. It is appreciated that the techniques are examples of suitable techniques for modifying a characteristic impedance of a plating bar and other techniques may be employed.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. A method comprising:
modifying a characteristic impedance along a length of a plating bar of a substrate package.

2. The method of claim 1, wherein modifying a characteristic impedance along a length of a plating bar comprises for a first length portion a continuous length of the plating bar, the plating bar has a first characteristic impedance and for a second length portion has a different second characteristic impedance.

3. The method of claim 1, wherein the second length portion is closer to a signal transmission line than the first length portion and the second characteristic impedance is less than the first characteristic impedance.

4. The method of claim 1, wherein the first length portion has width dimension that is less than a width dimension of the second length portion.

5. The method of claim 2, wherein a length of a plating bar may be defined by more than the first length portion and the second length portion.

6. The method of claim 2, wherein the substrate package comprises a ground plane and the plating bar is disposed on the substrate package over the ground plane, the method comprising:
removing a portion of the ground plane beneath the first length portion of the plating bar.

7. The method of claim 2, wherein the substrate package comprises a ground plane and the plating bar is disposed on the substrate package over the ground plane, the method comprising:
forming at least one opening in a portion of the ground plane beneath the first length portion of the plating bar.

8. An apparatus comprising:
a package substrate comprising a plurality of transmission lines therethrough, a portion of the plurality of transmission lines each comprising a plating bar coupled thereto, wherein the plating bar comprises portions having different characteristic impedance along its length.

9. The apparatus of claim 8, wherein each of the plating bars comprise a first length portion having a first characteristic impedance and a second length portion having a different second characteristic impedance.

10. The apparatus of claim 9, wherein the second length portion is closer to a signal transmission line than the first length portion and the second characteristic impedance is less than the first characteristic impedance.

11. The apparatus of claim 9, wherein the first length portion has width dimension that is less than a width dimension of the second length portion.

12. The apparatus of claim 9, wherein at least one plating bar may be defined by more than a first length portion and a second length portion.

13. The apparatus of claim 9, wherein the substrate package comprises a ground plane and the plating bar is disposed on the substrate package over the ground plane, wherein the ground plane is defined by the absence of a portion of the ground plane beneath the first length portion of the plating bar.

14. The apparatus of claim 9, wherein the substrate package comprises a ground plane and the plating bar is disposed on the substrate package over the ground plane, the ground plane comprising at least one opening in a portion of the ground plane beneath the first length portion of the plating bar.

15. A system comprising:
a computing device comprising a microprocessor, the microprocessor coupled to a printed circuit board through a substrate, the substrate comprising a plurality of transmission lines therethrough, a portion of the plurality of transmission lines each comprising a plating bar coupled thereto, wherein the plating bar comprises portions having different characteristic impedance along its length.

16. The system of claim 15, wherein each of the plating bars comprise a first length portion having a first characteristic impedance and a second length portion having a different second characteristic impedance.

17. The system of claim 16, wherein the second length portion is closer to a signal transmission line than the first length portion and the second characteristic impedance is less than the first characteristic impedance.

18. The system of claim 16, wherein the first length portion has width dimension that is less than a width dimension of the second length portion.

19. The system of claim 16, wherein the substrate package comprises a ground plane and the plating bar is disposed on the substrate package over the ground plane, wherein the ground plane is defined by the absence of a portion of the ground plane beneath the first length portion of the plating bar.

20. The system of claim 16, wherein the substrate package comprises a ground plane and the plating bar is disposed on the substrate package over the ground plane, the ground plane comprising at least one opening in a portion of the ground plane beneath the first length portion of the plating bar.
